(19) United States
(12) Patent Application Publication
(10) Pub. No.: US 2012/0112065 A1
(43) Pub. Date: May 10, 2012

(54) APPARATUS AND METHOD FOR ESTIMATING CHANGE OF STATUS OF PARTICLE BEAMS

(75) Inventors: Kuen-Yu TSAI, Taipei (TW); Sheng-Yung Chen, Taipei (TW)

(73) Assignee: National Taiwan University, Taipei City (TW)

(21) Appl. No.: 13/287,281

(22) Filed: Nov. 2, 2011

Related U.S. Application Data
(60) Provisional application No. 61/410,295, filed on Nov. 4, 2010.
(60) Provisional application No. 61/431,063, filed on Jan. 10, 2011.

(51) Int. Cl. H01J 37/29; G01J 1/42

(52) U.S. Cl. 250/307; 250/310; 250/309; 250/208.2

(57) ABSTRACT

This invention provides an apparatus for estimating change of status of a plurality of particle beams, the apparatus includes a plurality of particle detectors and an estimating unit, wherein the one or the plurality of particle beams is projected to a substrate. The particle detectors detect the one or the plurality of particle beams reflected from the substrate to generate one or a plurality of detector signals. The estimating unit estimates change of the status of the one or the plurality of particle beams by executing a mathematical programming method according to the one or the plurality of detector signals. By such arrangement and monitoring method, the apparatus could estimate the drift of beams.

### CROSS REFERENCE TO RELATED APPLICATIONS

This application claims the benefit of U.S. Provisional Application No. 61/410,295, filed on Nov. 4, 2010, and U.S. Provisional Application No. 61/431,063, filed on Jan. 10, 2011, the contents of which are incorporated herein by reference.

### BACKGROUND OF THE INVENTION

1. Field of the Invention

The present invention relates to an apparatus and method for estimating change of status of particle beams.

2. Description of the Prior Art

Microlithography, a process of transferring desired patterning information to a wafer, is one of the most critical processes in integrated circuit fabrication.

Currently, the mainstream lithography technology for high-volume manufacturing is optical projection with 193 nm deep-ultraviolet laser illumination and water immersion exposure. Its resolution, mainly limited by optical diffraction, has been below 45 nm in half-pitch. The associated process complexity and cost have grown prohibitively because strong resolution enhancement techniques are used to compensate for undesired diffraction effects. It is possible to achieve 32 nm half-pitch resolution by introducing double-patterning techniques. Several next-generation lithography techniques are being investigated for the 21 nm half-pitch node and beyond. Electron beam lithography is one of the promising candidates to complement optical projection lithography because of its high resolution and maskless capability.

Multiple-electron-beam-direct-write (MEBDW) lithography has been proposed and investigated to increase throughput. By utilizing micro-electromechanical-system (MEMS) processes for fabricating electron optical apparatus, the dimension of an electron beam lithography apparatus can be shrunk substantially. Theoretically, a massive amount of electron beams can be integrated and driven to expose the same wafer simultaneously. This architecture poses several engineering challenges to be conquered in order to achieve throughput comparable to optical projection lithography.

The beam quality of an electron beam lithography apparatus can degrade due to undesired effects such as electron charging and stray field. In multiple-electron-beam apparatus, beam positioning drift problems can become quite serious due to heat dissipation and electron optical apparatus (EOS) fabrication errors. Periodic recalibration with reference markers on the wafer has been utilized in single-beam apparatus to achieve beam placement accuracy.

However, it is difficult to extend technique of periodic recalibration for MEBDW because the complexity involves may increase significantly with beam numbers. Therefore, how to modify the current method and apparatus for monitoring particle beams in MEBDW lithography as a method or an apparatus which can estimate drift of multiple-beams has become an imminent task for the industries.

### SUMMARY OF THE INVENTION

The disclosure is directed to an apparatus and method for estimating change of status of particle beams. The reflected particle beams are detected by a plurality of particle detectors to generate a plurality of detector signals, and the estimating unit estimates the status of the particle beams by executing a mathematical programming method according to the detector signals so that the drift of beams could be estimated.

According to a first aspect of the present disclosure, an apparatus for estimating change of status of a plurality of particle beams is provided. The apparatus includes a plurality of particle detectors and an estimating unit, wherein the one or the plurality of particle beams is projected to a substrate. The particle detectors detect the one or the plurality of particle beams reflected from the substrate to generate one or a plurality of detector signals in response thereto. The estimating unit estimates change of the status of the one or the plurality of particle beams by executing a mathematical programming method according to the one or the plurality of detector signals.

According to a second aspect of the present disclosure, a method for estimating change of status of a plurality of particle beams is provided. The method includes the following steps: projecting one or a plurality of particle beams to a substrate; detecting the one or the plurality of particle beams reflected from the substrate by a plurality of particle detectors to generate one or a plurality of detector signals in response thereto; and executing a mathematical programming method by an estimating unit to estimate change of the status of the one or the plurality of particle beams according to the one or the plurality of detector signals.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1A shows a schematic view of an apparatus for estimating change of status of one or a plurality of particle beams by executing a mathematical programming method.

FIG. 1B (I) shows a schematic view of a two-dimensional array of particle detectors.

FIG. 1B (II) shows a schematic view of a detector group grouped of the four particle detectors A-D.

FIG. 1B (III) is an enlarged schematic view of the detector group.

FIG. 2 shows the simulation results of collection efficiency with various working distances obtained from 10,000 electrons incident to a silicon substrate.

FIG. 3 shows a flow chart of a method for estimating change of status of a plurality of particle beams.

FIG. 4 is a schematic view showing the particle beam deviates from the original beam axis and drifts toward the particle detector.

FIG. 5 shows a simulation result of the signals versus departures of the particle beam from the original beam axis.

FIG. 6 shows the statistic analysis of estimated position errors generated from two different methods.

FIGS. 7A-7B show the normalized β and r analysis of the LLS method with N=10³ to 10⁷, and the electron beam drift range is −0.1 μm to 0.1 μm with 10 nm distance step.

FIGS. 8A-8B show the total emission electrons (N) versus triple estimation errors (3σ) of three various defined ranges of electron beam drift by the LLS method.

### DETAILED DESCRIPTION OF THE PREFERRED EMBODIMENTS

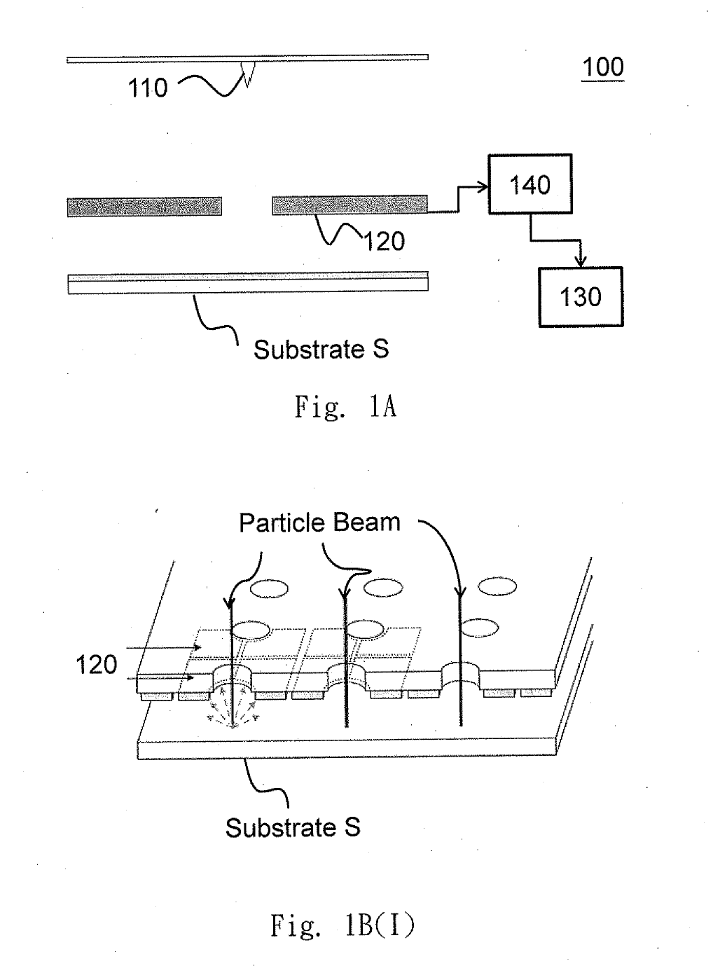

Referring to FIG. 1A, which shows a schematic view of an apparatus 100 for estimating change of status of one or a plurality of particle beams by executing a mathematical programming method, wherein the particle beams are used for being projected to a substrate S, and the status of the particle beams could represents particle energy per unit area or particle flux per unit area. The apparatus 100 includes a plurality of particle detectors 120 and an estimating unit 130. In one embodiment, the apparatus 100 could further include a plurality of beam sources 110 and a signal amplification unit 140.

The beam sources 110, such as photon beams, electron beams, ion beams or any combination thereof, could receive a control signal to provide one or a plurality of particle beams projected to a substrate S, wherein the particle beams could be substantially vertically projected to the substrate S.

The particle detectors 120, such as electron detectors, could detect the one or the plurality of particle beams reflected from the substrate S to generate one or a plurality of detector signals. In one embodiment, the particle detectors 120 could be disposed as an array of electron detectors placed above the substrate S, e.g. a wafer. In another embodiment, the particle detectors 120 could be quadrant-form two-dimensional detectors.

The estimating unit 130, such as a processing unit, could estimate the status of the one or the plurality of particle beams by executing a mathematical programming method according to the one or the plurality of detector signals. The status of the particle beams, for example, could represent the number of the reflected particles, particle energy, particle flux, the size, the shape, the position or the attitude of the particle beams. In one embodiment, the status of one or each of the particle beams is detected by at least two of the plurality of particle detectors. In another embodiment, the status of one or each of the particle beams is detected by at least four or the plurality of particle detectors.

The signal amplification unit 140, such as a signal amplifier, can amplify the detector signals and transmit the amplified detector signals to the estimating unit 130, wherein the estimating unit 130 could estimate status of the one or the plurality of particle beams according to the amplified detector signals. In one embodiment, the signal amplification unit 140 could be disposed inside the estimating unit 130 or particle detectors 120.

In one embodiment, every four of the particle detectors 120 are grouped so as to form one or a plurality of detector groups 125, and the one or each of the particle beams is projected to the substrate S through a center part of one or each of the detector groups. In another embodiment, the particle detectors 120, less than four or more than four, could be grouped to form one or a plurality of detector groups 125, and the one or each of the detector groups 125 corresponds to the one or each of the particle beams respectively, wherein the estimating unit 130 estimates status of the one or the plurality of particle beams according to the plurality of signals transmitted from the one or each of the detector groups 125.

For example, referring to FIG. 1B(I), which shows a schematic view of a two-dimensional array of the particle detectors 120 over the substrate S, in which every four particle detectors 120 are grouped so as to form a plurality of detector groups 125.

Please refer to FIG. 1B (II), which shows a schematic view of the detector group 125 grouped of the four particle detectors 120 A-D. The first particle beam projects through a center part of the first detector group, such as the four particle detectors 120 A-D, such that the first detector group generates signals D_{1,1}, D_{2,1}, D_{3,1} and D_{4,1} in response thereto, wherein the signals D_{1,1}, D_{2,1}, D_{3,1} and D_{4,1}, for example, are generated from the particle detectors 120 A-D. In signal D_{X,Y}, the X means this signal is generated from X-th particle detector of the detector groups, and the Y means this signal is generated from Y-th of detector groups; for example, the signal D_{1,1} is generated from the particle detector 120 A of the first detector group, the signal D_{4,1} is generated from the particle detector 120 D of the first detector group.

In addition, the four particle detectors 120 of the detector group 125 could sense the uneven backscattered distribution when the particle beam position is drifted from the central part. The particle beam projects to the substrate S through the center part of the detector group 125 such that the detector group 125 generates signals D_{1,1}, D_{2,1}, D_{3,1} and D_{4,1} in response thereto.

In one embodiment, the center part of the detector group 125 include a hole 122 for being passed by the particle beam. Referring to FIG. 1 B(III), which is an enlarged schematic view of the detector group, in which the hole 122, for example, could be set to 100 um, and the particle detectors could be set to 500 um in width while the beam pitch is 1 mm.

The particle detectors 120 can detect a distribution of back-scattered electrons. For each particle beam, the spatial distribution of back-scattered electrons depends on a distance between the ideal beam axis and the actual beam position. The ideal beam axis, for example, is an ideal path which particle beam projects. When a particle beam drifts to one side of the detector group 125 gradually, some detectors of the detector group 125 may observe ascending signals, while the other may observe descending signals. By comparing the magnitudes of detector signals, the value and direction of beam drift over time can be estimated. In one embodiment, each of the particle detectors 120 could has a non-planar surface to enhance the sensitivity for receiving the reflected particle beams.

Back to FIG. 1B(II), a working distance is defined to be a distance from the substrate S to a sensitive area of the particle detectors 120. A lower limit of the working distance is needed to ensure safe substrate exposure. An upper limit of the working distance is restricted by a collection efficiency, which is defined to be a ratio between a number of backscattered electrons that can be collected and a total number of backscattered electrons. It is a key indicator for designing the detector array since the main target is to collect electrons as much as possible to improve signal strength. In one embodiment, the working distance is between 0.2 mm-0.7 mm. In another embodiment, the working distance is 0.5 mm.

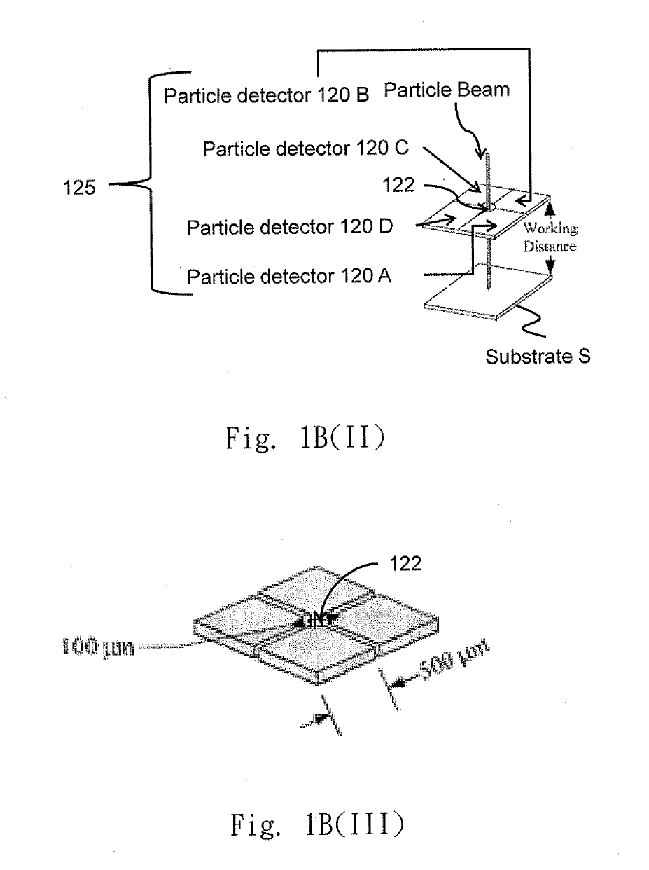

Refer to FIG. 2, which is a diagram showing simulation results of the collection efficiency with various working distances obtained from 10,000 electrons incident to a silicon substrate, wherein a beam spot size of the electrons is 10 nm and its incident energy is 1 keV. The result shows that the four detectors collection efficiency of the detector group 125 reaches its maximum of 80% when the working distance is about 0.2 mm. It is reduced to about 50% at 0.5 mm.

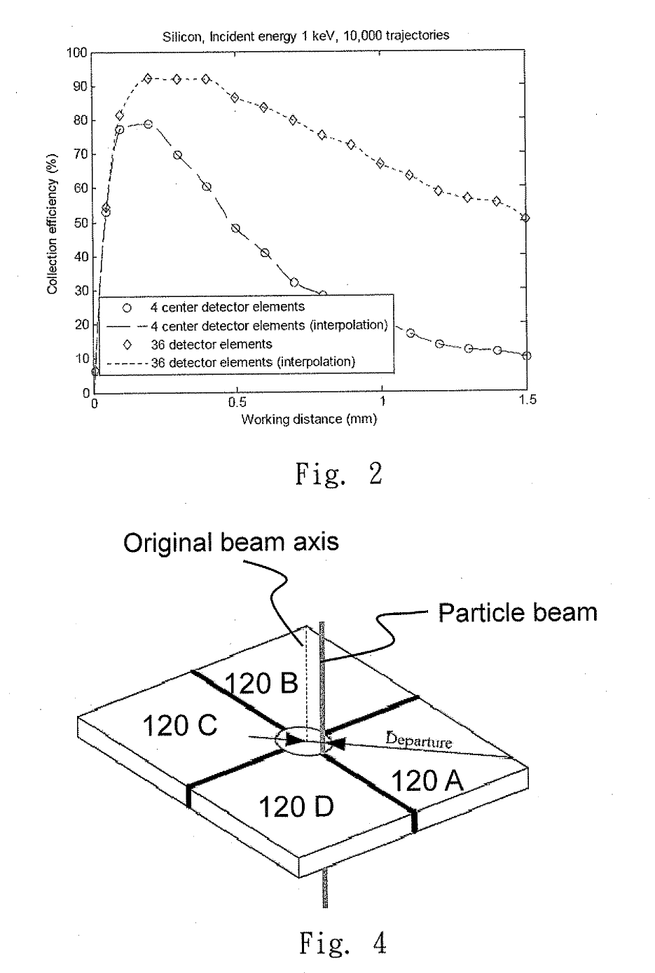

Refer to FIG. 3, which shows a flow chart of a method for estimating change of status of a plurality of particle beams 120 performed by the present apparatus, wherein the particle beams 120 are used for being projected to a substrate S. Please also refer to FIG. 1.

In step S310, projecting one or a plurality of particle beams by one or a plurality of beam sources 110. For example, the particle beam provided from the beam source 110 is projected through a hole of the detector group 125 to the substrate S.

In step S320, the one or the plurality of particle beams reflected from the substrate is detected by a plurality of particle detectors 120 to generate one or a plurality of signals. For example, refer to FIG. 1B(II), the reflected particle beams could be detected by particle detectors 120 A-D; however, in another embodiment, the reflected particle beams could be detected by other particle detectors other than the particle detectors 120 A-D.

In step S330, the signals are amplified by a signal amplification unit 140 to generate a plurality of amplified signals. The signal amplification unit 140, for example, amplifies the signals according to the strength of the signals.

In step S340, the statuses of the one or the plurality of particle beams is estimated by executing a mathematical programming method by an estimating unit 130 according to the signals or the amplified signals. In one embodiment, the apparatus 100 could further includes the amplification unit 140, then the estimating unit 130 would receive the amplified signals transmitted from the signal amplification unit 140, and the estimating unit 130 would estimate the status according to the amplified signals. In another embodiment, the apparatus 100 could not include the amplification unit 140, and the estimating unit 130 could estimate the status of the particle beams according to the signals transmitted from the particle detector 120.

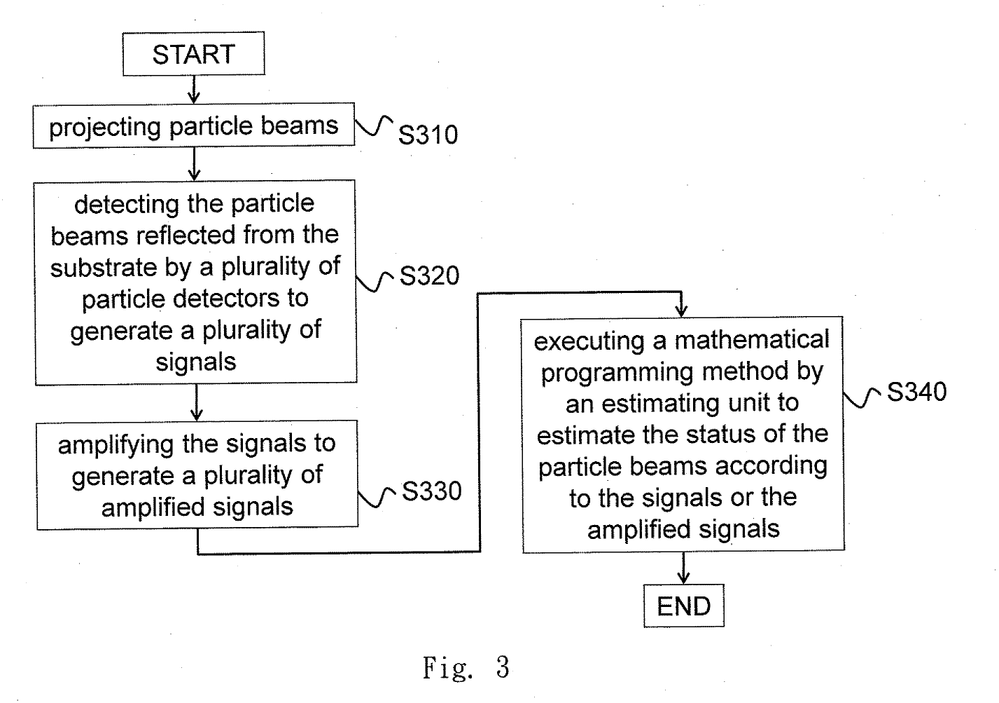

The status of the particle beams, for example, is a distance which the particle beam deviates from an original beam axis, wherein the particle beam may drift toward one particle detector 120. Refer to FIG. 4, which is a schematic view showing the particle beam deviates from the original beam axis and drifts toward the particle detector 120 A. The original beam axis passes through the central part of the detector group 125. In this example, the particle beam drifts toward the particle detector 120 A with a distance from 0 um to 50 um, the theoretical responsively of SPDs (Silicon Photodiode Detectors) with R_{A}=0.27 A/W¹⁰ is used; the working distance is set to 0.5 mm, and the incident current I_{O} is 10 nA.

In one embodiment, the mathematical programming method could be the Standard Quadrant Detection (SQD) method. The main algorithm of the detector group to estimate the status of the particle beams is shown as below Eq. (1).

$$X = \frac{( {D}_{1 , 1} + {D}_{4 , 1} ) - ( {D}_{2 , 1} + {D}_{3 , 1} )}{{D}_{1 , 1} + {D}_{2 , 1} + {D}_{3 , 1} + {D}_{4 , 1}} \cdot {F}_{x} = {k}_{x} \cdot {F}_{x} \\ Y = \frac{( {D}_{1 , 1} + {D}_{2 , 1} ) - ( {D}_{3 , 1} + {D}_{4 , 1} )}{{D}_{1 , 1} + {D}_{2 , 1} + {D}_{3 , 1} + {D}_{4 , 1}} \cdot {F}_{y} = {k}_{y} \cdot {F}_{y} \qquad ( 1 )$$

In Eq. (1), the signals D_{1,1}, D_{2,1}, D_{3,1} and D_{4,1} are generated from the particle detectors 120 A-120 D of first detector group; F_{X} and F_{Y} are constant values, for example, which are the scaling factors to adjust the range of detection; X and Y are one of the status of the particle beams, for example, which is the estimated positions. F_{X} and F_{Y} can be determined by applying a specified least-square method.

That is, the estimating unit 130 estimates an x-axis position of the first particle beam according to the difference between sum of the signals D_{1,1} and D_{4,1} and sum of the signals D_{2,1} and D_{3,1}, and the estimating unit 130 further estimates a y-axis position of the first particle beam according to the difference between sum of the signals D_{1,1} and D_{2,1} and sum of the signals D_{3,1} and the D_{4,1}.

How to do calibration of F_{X} and F_{Y} is very important in this mathematical programming method. A wide range of beam drift can be defined to establish a statistical table that estimates an unknown beam drifts position in this range. Because the obtained kₓ and k_{y} are dimensionless values, they can be scaled to meet the defined range of beam drift by using a least squares method (y=X β). The statistical table is then established, which can be easily implemented on the MEBDW (Multiple Electron Beam direct Write, MEBDW) system.

In another embodiment, the mathematical programming method could be the LLS (Linear Least squares, LLS) method. The least squares method is a standard approach to obtain approximate solutions of over determined systems, i.e. sets of equations in which there are more equations than unknowns. “Least squares” means that the overall solution minimizes the sum of the squares of the errors made in solving every single equation. For estimating unknown parameters, the best fit in the least squares sense minimizes the sum of squared residuals, a residual being the difference between an observed value and the value provided by a model. The least squares method corresponds to the maximum likelihood criterion if the experimental errors have a normal distribution.

For each assumed value of particle beam, in this embodiment, information of backscattered electrons, such as signals, detected from four particle detectors, such as particle detectors 120 A-D, is simulated. A series of statistical tables with various particle beam drift ranges of −10 um to 10 um, −1 um to 1 um, and −0.1 um to 0.1 um are established.

The linear least squares method is shown in Eq. (2) in a small beam drift range, where r ∈ R^{m×1}, β ∈ R^{m×n}, and X ∈ R^{n×1}.

y=Xβ+r (2)

The original point (0, 0), such as the central part of the detector group, is set as X₀, and a specific assumptive position of electron beam drift is set as X₂. Therefore, X₀ and X₂ can be shown as Eq. (3), and they are all given known variables.

$${X}_{0} = [ \begin{matrix}{x}_{1}^{0} \\ {x}_{2}^{0}\end{matrix} ] , and {X}_{2} = [ \begin{matrix}{x}_{1}^{2} \\ {x}_{2}^{2}\end{matrix} ] \qquad ( 3 )$$

The numbers of backscattered electrons detected from particle detectors. 120 at X₀ are denoted as Y₀, and those at X₂ as Y₂ shown as Eq. (4).

$${Y}_{0} = [ \begin{matrix}{y}_{1}^{0} \\ {y}_{2}^{0} \\ {y}_{3}^{0} \\ {y}_{4}^{0}\end{matrix} ] , and {Y}_{2} = [ \begin{matrix}{y}_{1}^{2} \\ {y}_{2}^{2} \\ {y}_{3}^{2} \\ {y}_{4}^{2}\end{matrix} ] \qquad ( 4 )$$

Such a system usually has no solution, and the goal is then to find the coefficients in β which fit the equations “best”, in the sense of solving the quadratic minimization problem in Eq. (5).

$${arg}_{β} min {\sum }_{i = 1}^{m} {\vert {y}_{i} - {\sum }_{j = 1}^{n} {X}_{ij} {β}_{j} \vert}^{2} = {arg}_{β} min {‖ y - X β ‖}^{2} = arg min {‖ r ‖}^{2} \qquad ( 5 )$$

From those least squares solutions, statistical tables of the various beam drift ranges are established.

The particle beams, reflected from the substrate, detected from the four particle detectors 120, such as particle detectors 120 A-D, at an unknown particle beam drift position denoted as X₁ are denoted as Y₁. The value of X₁ can be looked up from the statistical table with a suitable beam drift. The particle beam drift can be compensated by adjusting the particle beam since the table lookup can be very efficient computationally, such as shown in FIG. 4.

The first particle beam, passed through the detector group, could be detected by four particle detectors 120 of this group detector to generate four signals, and these four signals could be summarized in Eq. (6) and can be written as a matrix form in Eq. (7). There are six known include D_{1,i}, D_{2,i}, D_{3,l}, D_{4,l}, xᵢ and yᵢ, where D_{n,l} denotes the number of particle, reflected from the substrate, detected from particle detectors 120, such as particle detectors 120 A-D, at (xᵢ, yᵢ), and i means this signal is generated from which detector groups. Furthermore, there are twelve unknown variables include β₁, β₂, β₃, β₄, β₅, β₆, β₇, β₈, r₁, r₂, r₃, and r₄, where B is a scaling vector, and Γ is an offset vector.

$$\begin{matrix}\{ \begin{matrix}{D}_{1 , i} = {x}_{i} {β}_{1} + {y}_{i} {β}_{2} + {r}_{1} \\ {D}_{2 , i} = {x}_{i} {β}_{3} + {y}_{i} {β}_{4} + {r}_{2} \\ {D}_{3 , i} = {x}_{i} {β}_{5} + {y}_{i} {β}_{6} + {r}_{3} \\ {D}_{4 , i} = {x}_{i} {β}_{7} + {y}_{i} {β}_{8} + {r}_{4}\end{matrix} & ( 6 ) \\ [ \begin{matrix}{D}_{1 , i} \\ {D}_{2 , i} \\ {D}_{3 , i} \\ {D}_{4 , i}\end{matrix} ] = [ \begin{matrix}{x}_{i} & {y}_{i} & 0 & 0 & 0 & 0 & 0 & 0 \\ 0 & 0 & {x}_{i} & {y}_{i} & 0 & 0 & 0 & 0 \\ 0 & 0 & 0 & 0 & {x}_{i} & {y}_{i} & 0 & 0 \\ 0 & 0 & 0 & 0 & 0 & 0 & {x}_{i} & {y}_{i}\end{matrix} ] B + Γ & ( 7 )\end{matrix}$$

where B=[β₁ β₂ β₃ β₄ β₅ β₆ β₇ β₈]^{T}, and Γ=[r₁ r₂ r₃ r₄]^{T}

As a result, since the amount of drift of different particle beams in different detector group is similar to each other in MEBDW system, the different particle beams detected by the particle detectors of different detector groups can be obtained as

$$\begin{matrix}{D}_{1 , 1} = {β}_{1} {x}_{1} + {β}_{2} {y}_{1} + {r}_{1} \\ {D}_{1 , 2} = {β}_{1} {x}_{2} + {β}_{2} {y}_{2} + {r}_{1} \\ ⋮ \\ {D}_{1 , n} = {β}_{1} {x}_{n} + {β}_{2} {y}_{n} + {r}_{1} & ( 8 ) \\ [ \begin{matrix}{D}_{1 , 1} \\ {D}_{2 , 1} \\ {D}_{3 , 1} \\ {D}_{4 , 1} \\ {D}_{1 , 2} \\ {D}_{2 , 2} \\ {D}_{3 , 2} \\ {D}_{4 , 2} \\ ⋮ \\ {D}_{1 , n} \\ {D}_{2 , n} \\ {D}_{3 , n} \\ {D}_{4 , n}\end{matrix} ] = [ \begin{matrix}{x}_{1} & {y}_{1} & 0 & 0 & 0 & 0 & 0 & 0 \\ 0 & 0 & {x}_{1} & {y}_{1} & 0 & 0 & 0 & 0 \\ 0 & 0 & 0 & 0 & {x}_{1} & {y}_{1} & 0 & 0 \\ 0 & 0 & 0 & 0 & 0 & 0 & {x}_{1} & {y}_{1} \\ {x}_{2} & {y}_{2} & 0 & 0 & 0 & 0 & 0 & 0 \\ 0 & 0 & {x}_{2} & {y}_{2} & 0 & 0 & 0 & 0 \\ 0 & 0 & 0 & 0 & {x}_{2} & {y}_{2} & 0 & 0 \\ 0 & 0 & 0 & 0 & 0 & 0 & {x}_{2} & {y}_{2} \\ ⋮ & ⋮ & ⋮ & ⋮ & ⋮ & ⋮ & ⋮ & ⋮ \\ {x}_{n} & {y}_{n} & 0 & 0 & 0 & 0 & 0 & 0 \\ 0 & 0 & {x}_{n} & {y}_{n} & 0 & 0 & 0 & 0 \\ 0 & 0 & 0 & 0 & {x}_{n} & {y}_{n} & 0 & 0 \\ 0 & 0 & 0 & 0 & 0 & 0 & {x}_{n} & {y}_{n}\end{matrix} ] [ \begin{matrix}{β}_{1} \\ {β}_{2} \\ {β}_{3} \\ {β}_{4} \\ {β}_{5} \\ {β}_{6} \\ {β}_{7} \\ {β}_{8}\end{matrix} ] + [ \begin{matrix}{r}_{1} \\ {r}_{2} \\ {r}_{3} \\ {r}_{4} \\ {r}_{1} \\ {r}_{2} \\ {r}_{3} \\ {r}_{4} \\ ⋮ \\ {r}_{1} \\ {r}_{2} \\ {r}_{3} \\ {r}_{4}\end{matrix} ] & ( 9 )\end{matrix}$$

By combing similar equations for the second particle detector, such as particle detector 120 B, to the fourth particle detector, such as particle detector 120 D, all the equations can be arranged as Eq. (9). By using the LLS method, all the unknown variables can be calculated.

In one embodiment, the first particle beam projects through a center part of a first detector group such that the first detector group generates signals D_{1,1}, D_{2,1}, D_{3,1} and D_{4,1} in response thereto, the second particle beam projects through a center part of a second detector group such that the second detector group generates signals D_{1,2}, D_{2,2}, D_{3,2} and D_{4,2} in response thereto, a third particle beam projects through a center part of a third detector group such that the third detector group generates signals D_{1,3}, D_{2,3}, D_{3,3} and D_{4,3} in response thereto; then the estimating unit 130 would estimate β₁, β₂ and γ₁ according to the signals D_{1,1}, D_{1,2} and D_{1,3} by executing a mathematical programming method, such as shown in Eq. (10); wherein the (xₙ, yₙ) is the position which the n-th particle beam pass through.

D_{1,1}=β₁x₁+β₂y₁+r₁

D_{1,2}=β₁x₂+β₂y₂+r₁

D_{1,3}=β₁x₃+β₂y₃+r₁ (10)

Similar to Eq. (10), the estimating unit 130 could estimate β₃, β₄ and γ₂ according to the signals D_{2,1}, D_{2,2} and D_{2,3}; in addition, the estimating unit 130 could estimate β₅, β₆ and γ₃ according to the signals D_{3,1} D_{3,2} and D_{3,3}; furthermore, the estimating unit 130 could estimate β₇, β₈ and γ₄ according to the signals D_{4,1}, D_{4,2} and D_{4,3}.

That is, the estimating unit 130 could estimate the status of the particle beams by using a mathematical programming method, such as Eq. (9), according to the signals, β₁˜β₈ and γ₁˜γ₄. In other words, the particle detectors 120 could generate the signals D_{1,k}-D_{4,k}, the estimating unit 130 estimates the status of the particle beams according to the signals D_{1,k}-D_{4,k} by using following equations: D_{1,k}=β₁Xₖ+β₂Yₖ +γ₁; D2,k=β₃Xₖ+β₄Yₖ+γ₂; D_{3,k}=β₅Xₖ+β₆Yₖ+γγ₃; and D_{4,k}=β₇Xₖ+β₈Yₖ+γ₄; wherein (Xₖ, Yₖ) is the status of the particle beams and the mathematical programming method is a linear least-squares method, the linear least-squares is arg min ∥Y^{k}−Xₖβ∥²;

$$wherein β = \frac{- {β}_{1}}{{β}_{2}} , \frac{- {β}_{3}}{{β}_{4}} , \frac{- {β}_{5}}{{β}_{6}} , or \frac{- {β}_{7}}{{β}_{8}} .$$

Therefore, any unknown beam position (xₖ, yₖ) can be determined by the Eq. (7) with the information of backscattered electrons detected from four particle detector of detector group, such as D_{1,k}, D_{2,k}, D_{3,k}, and D_{4,k}.

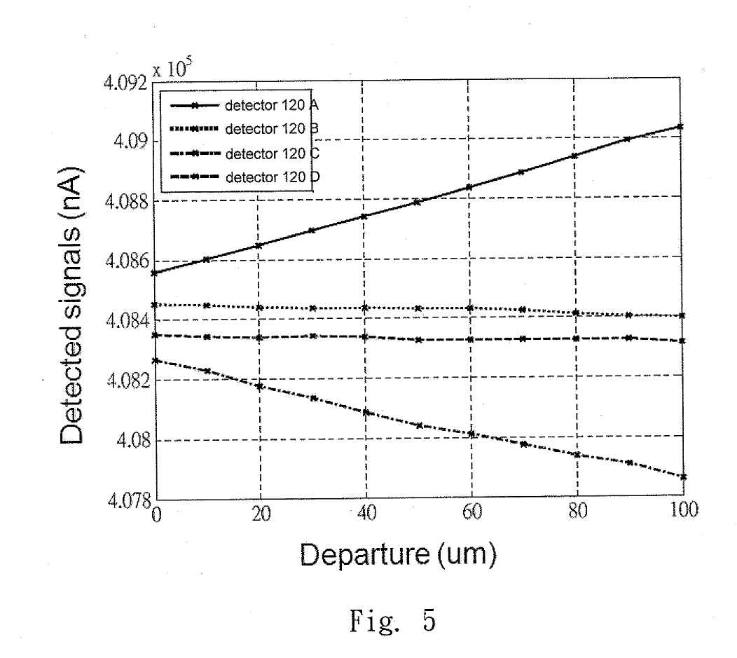

FIG. 5 shows a simulation result of the signals versus departures of the particle beam from the original beam axis. Due to symmetry, the signals detected from the particle detector 120 B and the particle detector 120 D are expected to be nearly identical. The small difference is due to the stochastic effects of simulation. The amount of detected signal generated from particle detector 120 A increases from 408,560 to 409,034. The amount of detected signal generated from particle detector 120 C decreases from 408,265 to 407,861. The differential sensitive is about 4˜5 electrons per nm.

In this embodiment, the four particle detectors 120 A-D composing the detector group are disposed symmetrically such that two signals of the detector group are substantially equal to each other, and an amount of difference of another two signals of the detector group increases with increase of a distance between the particle beam and the center part of the detector group when the particle beam drifts toward one of the four particle detectors, e.g. the particle detector 120A. That is, in this embodiment, the estimating unit 130 could estimate the drift status of the particle beam according to the amount of difference between signals of the particle detectors 120 A and 120C.

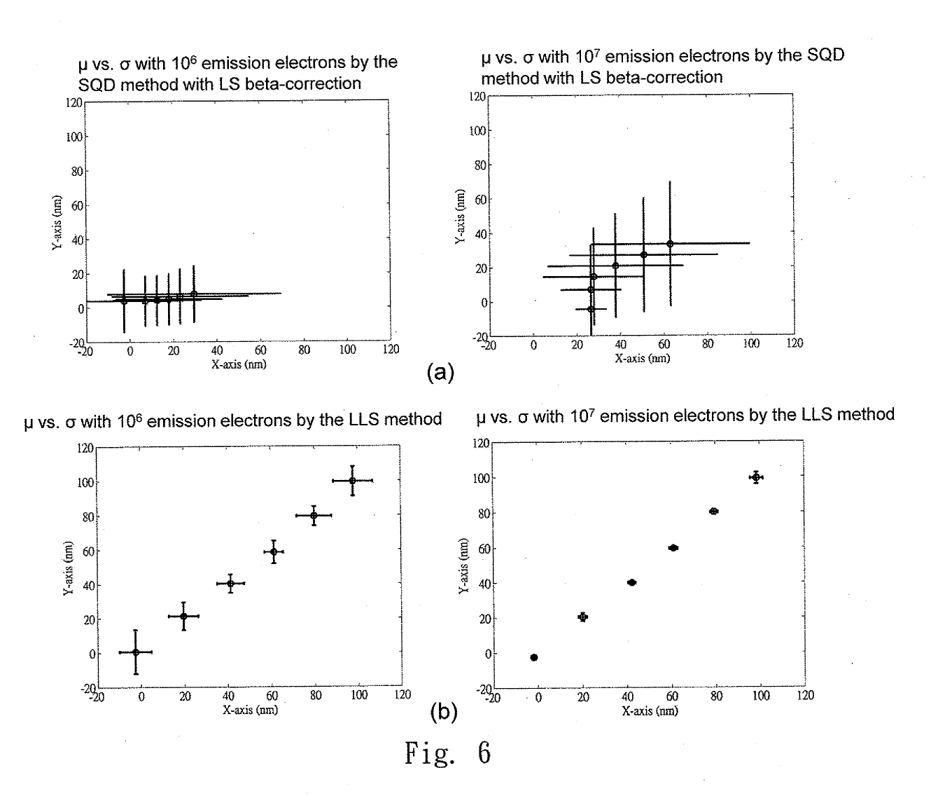

FIG. 6 shows the statistic analysis of estimated position errors generated from two different methods, SQD method with least-squares beta-correction and LLS method, under 10⁵ to 10⁷ emission electrons by the average of ten simulation runs and three various defined electron beam drift ranges, where u is the mean estimated position and a is the standard deviation. In the case of 10⁵ emission electrons, the errors and the standard deviations have dramatic variations. From the estimated results with 10⁶ to 10⁷ emission electrons, the errors fall into a more reasonable range.

In the cases of 10⁶ and 10⁷ emission electrons, the results of using the SQD method with least-squares beta-correction indicate that the estimated positions cannot clearly identify while the estimated positions can identify well using the LLS method. In order to improve the estimation errors, the LLS method is chosen as the main algorithm in the following simulations. The variation errors decrease as the number of emission electrons increases.

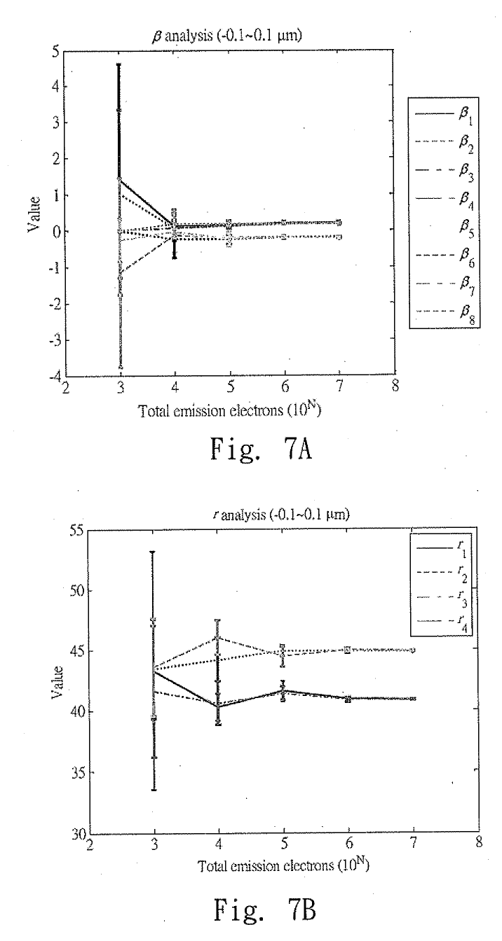

FIGS. 7A-7B show the normalized β and r analysis of the LLS method with N=10³ to 10⁷, and the electron beam drift range is −0.1 μm to 0.1 μm with 10 nm distance step. From those results, the variations of β and r decrease to stable values with increased the number of emission electrons.

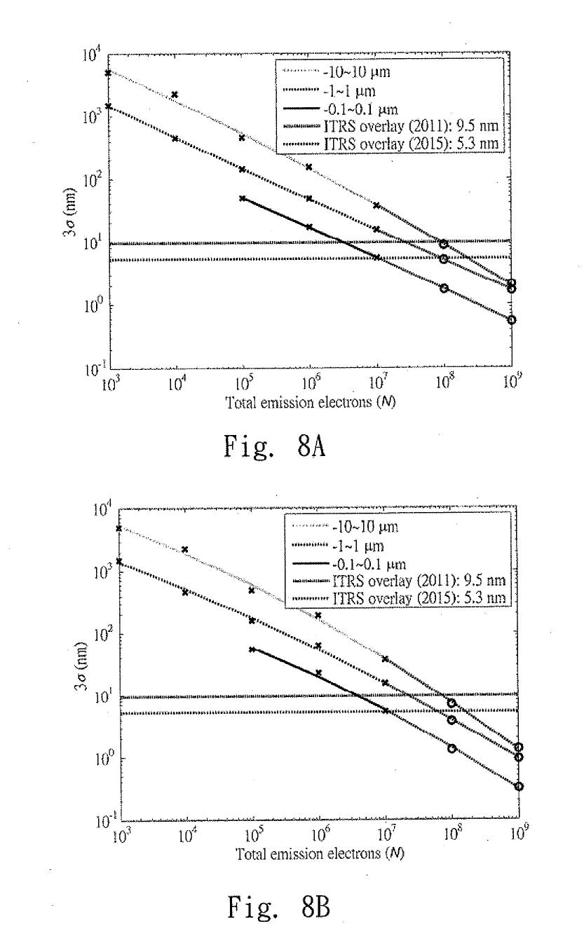

FIG. 8A shows the total emission electrons (N) versus triple estimation errors (3σ) of three various defined ranges of electron beam drift by the LLS method, where −10˜10 μm represents the beam drift range is −10 μm to 10 μm with 1 μm distance step, −1˜1 μm represents the beam drift range is −1 μm to 1 μm with 100 nm distance step, and −0.1−0.1 μm represents the beam drift range is −0.1 μm to 0.1 μm with 10 nm distance step. Due to not enough emission electrons, theσ values of 10³ and 10⁴ with the beam drift from −0.1 μm to 0.1 μm fall into an infeasible range. Therefore, those data can be ignored. The cross marks show 10³ to 10⁷ emission electrons. Those curves present a linear-log approach when the number of emission electrons is large enough. Therefore, the extrapolation method is applied to estimate the trend of N equal to 10⁸ and 10⁹, which are shown with circle marks.

The required 3-sigma overlay accuracy of MPU defined in ITRS (International Technology Roadmap for Semiconductors, ITRS) roadmap is 9.5 nm at the 38 nm half-pitch node while the gate length is 35 nm, and 5.3 nm at the 21 nm half-pitch node while the gate length is 22 nm. In order to achieve these requirements, more than 10⁹ emission electrons are needed in all simulations.

FIG. 8B is obtained by applying the estimated values of β and r from 10⁷ emission electrons to the cases of 10³˜10⁶ emission electrons. The estimated errors decrease slightly for N equal to 10⁸˜10⁹ while the errors increase slightly for N equal to 10³˜10⁶.

According to the apparatus and method for estimating change of status of a plurality of particle beams, wherein the reflected particle beams are detected by a plurality of particle detectors to generate a plurality of signals, and the estimating unit estimates change of the status of the particle beams by executing a mathematical programming method according to the signals so that the drift of beams could be estimated. Therefore, the apparatus and method for estimating change of status of particle beams of the disclosure at least has the feature of “could estimate the status of particle beams and achieve beam placement accuracy”.

What is claimed is:

1. An apparatus for estimating change of status of one or a plurality of particle beams, comprising:
one or a plurality of particle beams projected to a substrate;
a plurality of particle detectors, used for detecting the one or the plurality of particle beams reflected from the substrate to generate one or a plurality of detector signals in response thereto; and
an estimating unit, used for estimating change of the status of the one or the plurality of particle beams by executing a mathematical programming method according to the one or the plurality of detector signals.

2. The apparatus for estimating change of status of one or a plurality of particle beams of claim 1, wherein the particle beams are photon beams, electron beams, ion beams or any combination thereof.

3. The apparatus for estimating change of status of one or a plurality of particle beams of claim 1, wherein the status of the one or the plurality of particle beams represents particle energy or particle flux of the one or each of the particle beams.

4. The apparatus for estimating change of status of one or a plurality of particle beams of claim 1, wherein the status of the one or the plurality of particle beams represents size, shape, position, or attitude of the one or each of the plurality of particle beams.

5. The apparatus for estimating change of status of one or a plurality of particle beams of claim 1, further comprising:
a signal amplification unit, used for amplifying the one or the plurality of detector signals to generate one or a plurality of amplified detector signals respectively, wherein the, estimating unit estimates change of the status of the one or the plurality of particle beams according to the one or the plurality of amplified detector signals.

6. The apparatus for estimating change of status of one or a plurality of particle beams of claim 1, wherein the mathematical programming method is the linear least-squares method.

7. The apparatus for estimating change of status of one or a plurality of particle beams of claim 1, wherein the particle detectors are grouped so as to form one or a plurality of detector groups, the one or each of the detector groups corresponds to the one or each of the particle beams respectively, and the estimating unit estimates change of status of the one or the plurality of particle beams according to the one or the plurality of detector signals transmitted from the one or each of the plurality of detector groups.

8. The apparatus for estimating change of status of one or a plurality of particle beams of claim 7, wherein the particle detectors are grouped so as to form one or a plurality of detector groups, and a first particle beam projects through a center part of a first detector groups such that the first detector group generates signals D_{1,1}, D_{2,1}, D_{3,1} and D_{4,1} in response thereto.

9. The apparatus for estimating change of status of one or a plurality particle beams of claim 8, wherein the estimating unit estimates an x-axis position of the first particle beam according to the difference between sum of the signals D_{1,1} and D_{4,1} and sum of the signals D_{2,1} and D_{3,1}, and the estimating unit further estimates a y-axis position of the first particle beam according to the difference between sum of the signals D_{1,1} and D_{2,1} and sum of the signals D_{3,1} and the D_{4,1}.

10. The apparatus for estimating change of status of one or a plurality particle beams of claim 9, wherein the mathematical programming method is standard quadrant detection, the standard quadrant detection comprises:
$$X = \frac{( {D}_{1 , 1} + {D}_{4 , 1} ) - ( {D}_{2 , 1} + {D}_{3 , 1} )}{( {D}_{1 , 1} + {D}_{2 , 1} + {D}_{3 , 1} + {D}_{4 , 1} )} \cdot {F}_{X} ; and$$
$$Y = \frac{( {D}_{1 , 1} + {D}_{2 , 1} ) - ( {D}_{3 , 1} + {D}_{4 , 1} )}{( {D}_{1 , 1} + {D}_{2 , 1} + {D}_{3 , 1} + {D}_{4 , 1} )} \cdot {F}_{Y} ;$$
wherein the F_{X} and F_{Y} are scaling factors which affect the range of detection, and the X and Y are one of the status of the particle beams, and F_{X} and F_{Y} are determined by applying a specified least-square method.

11. A method for estimating change of status of one or a plurality of particle beams, comprising:
projecting one or a plurality of particle beams to a substrate;
detecting the one or the plurality of particle beams reflected from the substrate by a plurality of particle detectors to generate one or a plurality of detector signals in response thereto; and
executing a mathematical programming method by an estimating unit to estimate change of the status of the one or the plurality of particle beams according to the one or the plurality of detector signals.

12. The method for estimating change of status of one or a plurality particle beams of claim 11, wherein the particle beams are photon beams, electron beams, ion beams or any combination thereof.

13. The method for estimating change of status of one or a plurality of particle beams of claim 11, wherein the status of the one or the plurality of particle beams represents particle energy or particle flux of the one or each of the particle beams.

14. The method for estimating change of status of one or a plurality particle beams of claim 11, wherein the status of the one or the plurality of particle beams represents size, shape, position, or attitude of the one or each of the plurality of particle beams.

15. The method for estimating change of status of one or a plurality of particle beams of claim 11, further comprising:
amplifying the one or the plurality of detector signals by a signal amplification unit to generate one or a plurality of amplified detector signals respectively, wherein the estimating unit estimates change of the status of the one or the plurality of particle beams according to the one or the plurality of amplified detector signals.

16. The method for estimating change of status of one or a plurality of particle beams of claim 11, wherein the mathematical programming method is the linear least-squares method.

17. The method for estimating change of status of one or a plurality particle beams of claim 11, wherein the particle detectors are grouped so as to form one or a plurality of detector groups, the one or each of the detector groups corresponds to the one or each of the plurality of particle beams respectively, and the estimating unit estimates change of status of the one or the plurality of particle beams according to the one or the plurality of detector signals transmitted from the one or each of the detector groups.

18. The method for estimating change of status of one or a plurality particle beams of claim 17, wherein the particle detectors are grouped so as to form one or a plurality of detector groups, and a first particle beam projects through a center part of a first detector groups such that the first detector group generates signals D_{1,1}, D_{2,1}, D_{3,1} and D_{4,1} in response thereto.

19. The method for estimating change of status of one or a plurality particle beams of claim 18, wherein the estimating unit estimates an x-axis position of the first particle beams according to the difference between sum of the signals D_{1,1} and D_{4,1} and sum of the signals D_{2,1} and D_{3,1}, and the estimating unit further estimates a y-axis position of the first particle beams according to the difference between sum of the signals D_{1,1} and D_{2,1} and sum of the signals D_{3,1} and the D_{4,1}.

20. The method for estimating change of status of one or a plurality particle beams of claim 19, wherein the mathematical programming method is standard quadrant detection, the standard quadrant detection are
$$X = \frac{( {D}_{1 , 1} + {D}_{4 , 1} ) - ( {D}_{2 , 1} + {D}_{3 , 1} )}{( {D}_{1 , 1} + {D}_{2 , 1} + {D}_{3 , 1} + {D}_{4 , 1} )} \cdot {F}_{X} ;$$
$$Y = \frac{( {D}_{1 , 1} + {D}_{2 , 1} ) - ( {D}_{3 , 1} + {D}_{4 , 1} )}{( {D}_{1 , 1} + {D}_{2 , 1} + {D}_{3 , 1} + {D}_{4 , 1} )} \cdot {F}_{Y} ;$$
wherein the F_{X} and F_{Y} are scaling factors which affect the range of detection, and the X and Y are one of the status of the particle beams, and F_{X} and F_{Y} are determined by applying a specified least-square method.
